(19) United States
(12) Patent Application Publication
(10) Pub. No.: US 2009/0146142 A1
(43) Pub. Date: Jun. 11, 2009

(54) Light-emitting device including nanorod and method of manufacturing the same

(75) Inventors: Kyoung-kook Kim, Suwon-si (KR); Joo-sung Kim, Yongin-si (KR); Young-soo Park, Yongin-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 12/076,608

(22) Filed: Mar. 20, 2008

(30) Foreign Application Priority Data
Dec. 5, 2007 (KR) 10-2007-0125767

(51) Int. Cl. H01L 33/00; H01L 21/205

(52) U.S. Cl. 257/43; 257/88; 438/46; 977/762; 257/E33.006; 257/E33.019; 257/E33.063; 257/E21.101

(57) ABSTRACT

Provided are a light-emitting device including a plurality of nanorods each of which comprises an active layer formed between an n-type region and a p-type region, and a method of manufacturing the same. The light-emitting device comprises: a substrate; a first electrode layer formed on the substrate; a basal layer formed on the first electrode layer; a plurality of nanorods formed vertically on the basal layer, each of which comprises a bottom part doped with first type, a top part doped with second type opposite to the first type, and an active layer between the bottom part and the top part, an insulating region formed between the nanorods, and a second electrode layer formed on the nanorods and the insulating region.

### CROSS-REFERENCE TO RELATED PATENT APPLICATION

This application claims the benefit of Korean Patent Application No. 10-2007-0125767, filed on Dec. 5, 2007, in the Korean Intellectual Property Office, the disclosure of which is incorporated herein in its entirety by reference.

### BACKGROUND OF THE INVENTION

1. Field of the Invention

The present invention relates to a light-emitting device including a plurality of nanorods, and a method of manufacturing the same, and more particularly, to a light-emitting device including a plurality of nanorods each of which comprises an active layer formed between an n-type region and a p-type region, and a method of manufacturing the light-emitting device.

2. Description of the Related Art

Galium nitride (GaN)-based compound semiconductors are currently being researched as materials for light-emitting devices. GaN-based compound semiconductors have a wide band gap, and can provide light of almost all wavelength bands, that is, from visible light to ultraviolet rays, depending on the composition of the nitride. However, when a GaN-based compound semiconductor is grown into a thin nitride film, problems such as dislocation, grain boundary, or point defects may arise during the thin film growth, and therefore light-emitting devices using GaN-based compound semiconductors have low light-emitting efficiency due to such defects.

In order to increase light-emitting efficiency, research is being conducted into a technology of producing a nano-scale light-emitting device using a GaN-based compound semiconductor or a zinc oxide to form a p-n junction in a one-dimensional bar or line-shaped nanobar form, that is, in a nanorod or nanowire form. However, nanorods or nanowires are very vulnerable to external forces, and it is difficult to form an electrode material between nanorods or nanowires through a simple deposition. Moreover, if the nanostructure is covered with a metal layer, light transmittance is decreased, making it difficult to stably manufacture the light-emitting device. Therefore, a light-emitting device with a novel nanostructure is needed in order to stably implement a light-emitting device using nanorods or nanowires.

### SUMMARY OF THE INVENTION

The present invention provides a light-emitting device including a plurality of nanorods each of which comprises an active layer formed between an n-doped region and a p-doped region, and a method of manufacturing the same.

According to an aspect of the present invention, there is provided a light-emitting device including: a substrate; a first electrode layer formed on the substrate; a basal layer formed on the first electrode layer; a plurality of nanorods formed vertically on the basal layer, including a bottom part doped with first type, a top part doped with second type opposite to the first type, and an active layer between the bottom part and the top part; insulating region formed between the nanorods; and a second electrode layer formed on the nanorods and the insulating region.

According to an embodiment of the present invention, the bottom parts of the nanorods and the basal layer may be formed of an n-type zinc oxide, and the top parts of the nanorods may be formed of a p-type zinc oxide.

According to another embodiment of the present invention, the basal layer and the bottom parts of the nanorods may be formed of a p-type zinc oxide, and the top parts of the nanorods may be formed of an n-type zinc oxide.

The insulating region may include, for example, silicon oxide, silicon nitride, or magnesium fluoride.

In addition, each of the first and the second electrode layers may be formed of a transition metal, or an alloy including the transition metal.

According to another aspect of the present invention, there is provided a light-emitting device including: a conductive substrate; a first electrode layer formed below the substrate; a basal layer formed on top of the substrate; a plurality of nanorods formed vertically on the basal layer, and including a bottom part doped with first type, a top part doped with second type opposite to the first type, and an active layer between the bottom part and the top part; an insulating region formed between the nanorods; and a second electrode layer formed on the nanorods and the insulating region.

According to another aspect of the present invention, there is provided a method of manufacturing the light-emitting device including: forming a first electrode layer on a substrate; forming a basal layer on top of the first electrode layer; forming a plurality of nanorods vertically on the basal layer, wherein the nanorods include a bottom part doped with first type, a top part doped with second type opposite to the first type, and an active layer between the bottom part and the top part; forming an insulating region between the nanorods; and forming a second electrode layer on the nanorods and the insulating region.

Here, the basal layer may be formed using a chemical vapor-phase deposition method at a V/II ratio of 10 to 1000, a temperature of 200 to 800° C., a pressure of 100 to 1000 mbar, with diethyl zinc and oxygen gas as raw materials.

For example, the thickness of the basal layer may be less than 1 μm.

Furthermore, the nanorods may be formed using a chemical vapor-phase deposition at a V/II ratio of 10 to 1000, a temperature of 500 to 800° C., and a pressure of 10 to 500 mbar, with diethyl zinc and oxygen gas as raw materials.

According to the present invention, the insulating region may be formed of a mixture of, for example, silicon oxide and magnesium fluoride.

In addition, according to the present invention, the insulating region may be disposed on a lower part of the nanorods, and the second electrode layer may be disposed on an upper part of the nanorods.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a simplified structure of a light-emitting device including nanorods, according to an embodiment of the present invention;

FIGS. 2A to 2E are cross-sectional views illustrating a method of manufacturing the light-emitting device illustrated in FIG. 1, according to an embodiment of the present invention;

FIG. 3 is a scanning electron microscopy (SEM) image of nanorods formed using the process described with reference to FIG. 2B, according to an embodiment of the present invention; and

FIG. 4 is a graph illustrating a light-emitting characteristic of the light-emitting device shown in FIG. 1, according to an embodiment of the present invention.

### DETAILED DESCRIPTION OF THE INVENTION

Hereinafter, the present invention will be described more fully with reference to the accompanying drawings, in which preferred embodiments of the invention are shown. The following exemplary embodiments, however, are not intended to limit the scope of the present invention, and these embodiments are provided so that this disclosure will sufficiently describe the concept of the invention to those skilled in the art. In the drawings, like reference numerals denote like elements, and the size of each element may be exaggerated for clarity and convenience.

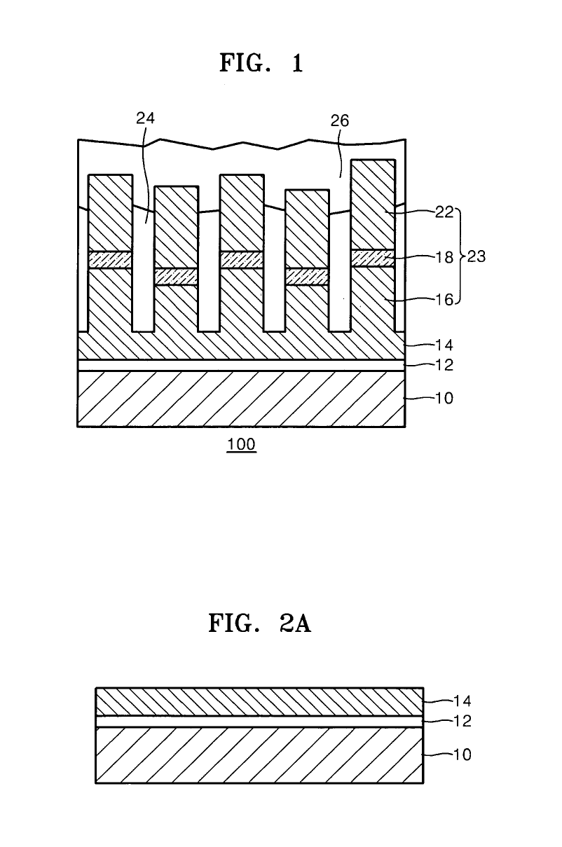

FIG. 1 is a cross-sectional view of a simplified structure of a light-emitting device 100 including a plurality of nanorods 23, according to an embodiment of the present invention. The light emitting device 100 according to the current embodiment includes a substrate 10, a first electrode layer 12, a basal layer 14, the plurality of nanorods 23, and insulating region 24 between the nanorods 23. In particular, the first electrode layer 12 and the basal layer 14 are formed on the substrate 10, and the plurality of nanorods 23, which are formed of zinc oxide, are formed vertically on the basal layer 14. Each nanorod 23 includes a bottom part 16 doped with n-type and a top part 22 doped with p-type, and an active layer 18 formed between the bottom parts 16 and the top parts 22. However, the present invention is not limited thereto, and the bottom part 16 may be doped with p-type, and the top part 22 may be doped with n-type. Moreover, the insulating region 24 is formed between the nanorods 23, and a second electrode layer 26 is formed on the nanorods 23 and the insulating region 24.

According to an embodiment of the present invention, since the nanorods 23 have a low defect density, the nanorods 23 have high internal quantum efficiency and external quantum efficiency compared to a thin-film type light-emitting device. Therefore, the self-absorption of the light emitted from each nanorod 23 of the light-emitting device 100 according to the current embodiment of the present invention is very low compared to a thin-film light-emitting device, and external quantum efficiency may be enhanced due to an advantageous structure for extracting the light to the outside.

The substrate 10 may be formed of silicon, sapphire, zinc oxide, indium tin oxide (ITO), flat metal thin film, glass, or quartz.

Moreover, each of the first electrode layer 12 and the second electrode layer 26 may be formed of a transition metal or an alloy including at least one of the transition metals. More particularly, each of the first electrode layer 12 and the second electrode layer 26 may include at least one metal selected from the group consisting of Ru, Hf, Ir, Mo, Re, W, V, Pd, Ta, Ti, Au, Al, and Pt. FIG. 1 shows the first electrode layer 12 formed on the upper surface of the substrate 10, but the in a case where the substrate 10 is formed of a conductive material such as silicon, zinc oxide, indium tin oxide, or a metal thin film, the first electrode layer 12 may be formed on the bottom surface the substrate 10.

Meanwhile, the basal layer 14 may be formed of n-type zinc oxide or p-type zinc oxide. The basal layer 14 may be composed of the same material as the bottom parts 16 of the nanorods 23, in order to reduce crystal misalignment with the nanorods 23. For example, if the bottom parts 16 of the nanorods 23 are formed of n-type zinc oxide, the basal layer 14 may also be formed of n-type zinc oxide, and if the bottom parts 16 of the nanorods 23 are formed of p-type zinc oxide, the basal layer 14 may also be formed of p-type zinc oxide. Moreover, the surface of the basal layer 14 should be formed to be flat, in order to form nanorods 23 with excellent orientation in a C-axis direction. According to an embodiment of the present invention, the basal layer 14 may be formed using a chemical vapor-phase deposition (CVD) method at a V/II ratio of 10 to 1000, a temperature of 200 to 800° C., a pressure of 100 to 1000 mbar, with diethyl zinc and oxygen gas as raw materials. The thickness of the basal layer 14 may be formed to be no more than 1 μm, more preferably, about 1000 to 3000 Å.

Referring to FIG. 1, the plurality of nanorods 23 composed of zinc oxide are formed vertically on the basal layer 14. The nanorods 23 may include the bottom parts 16 doped with n-type and top parts 22 doped with p-type, and the active layer 18 formed between the bottom parts 16 and the top parts 22. According to an embodiment of the present invention, the nanorods 23 may be formed using a CVD method at a V/II ratio of 10 to 1000, a temperature of 500 to 800° C., and a pressure of 10 to 500 mbar, with diethyl zinc and oxygen gas as raw materials. Here, the bottom parts 16 of the nanorods 23 may be formed of n-type zinc oxide, and the top parts 22 may be formed of p-type zinc oxide. However, as previously described, the present invention is not limited thereto, and the bottom parts 16 of the nanorods 23 may be formed of p-type zinc oxide, and the top parts 22 may be formed of n-type zinc oxide.

In addition, the active layer 18 formed between the bottom parts 16 and the top parts 22 of the nanorods 23, may have a multi-quantum well (MQW) structure including at least one quantum well layer formed of zinc oxide (ZnO), and at least one barrier layer formed of zinc-magnesium oxide (ZnMgO).

Meanwhile, the insulating region 24 is formed between the nanorods 23. The insulating region 24 may be formed of a material such as silicon oxide (SiO₂), silicon nitride (SiN), or magnesium fluoride (MgF₂). Alternatively, the insulating region 24 may be formed by mixing silicon oxide and magnesium fluoride having a refractive index of about 1.2 to 1.4.

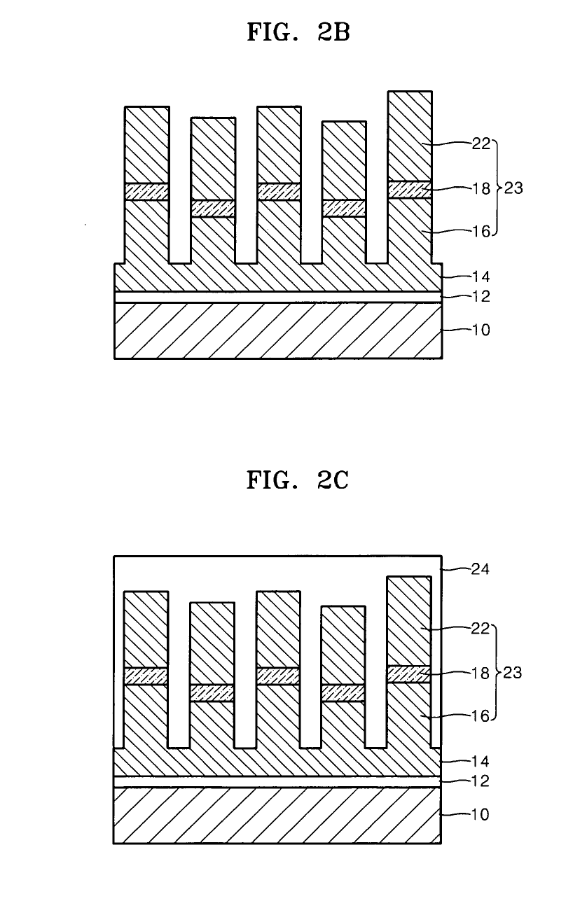

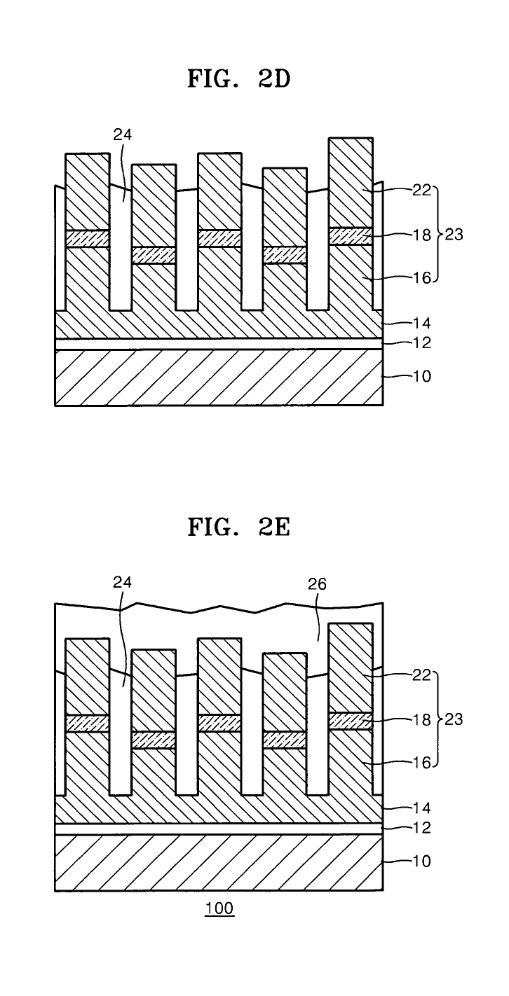

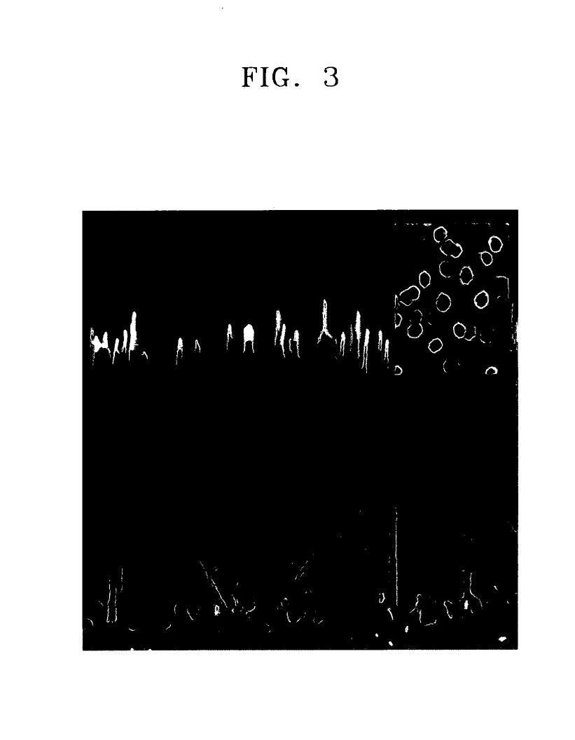

FIGS. 2A to 2E are cross-sectional views illustrating a method of manufacturing the light-emitting device 100 illustrated in FIG. 1, according to an embodiment of the present invention.

First, referring to FIG. 2A, a first electrode layer 12 and a basal layer 14 are formed consecutively on a substrate 10 formed of, for example, silicon. However, if the substrate 10 is formed of a conductive material, the first electrode layer 12 may be formed below the substrate 10. In this case, the basal layer 14 will be formed directly on the substrate 10. The first electrode layer 12 may be formed of platinum, so that it can form an ohmic contact with the basal layer 14 formed thereon. In addition, the basal layer 14 may be formed of n-type zinc oxide. According to an embodiment of the present invention, the basal layer 14 may be formed to a thickness of about 2000 Å using a CVD method at a V/II ratio of about 120, a temperature of about 450° C., and a pressure of about 100 mbar, using diethyl zinc and oxygen gas as raw materials.

Next, referring to FIG. 2B, a plurality of nanorods 23 each including a bottom part 16 formed of n-type zinc oxide, an active layer 18 including zinc magnesium oxide, and top parts 22 formed of p-type zinc oxide are vertically formed on the basal layer 14 formed of the n-type zinc oxide. According to an embodiment of the present invention, the bottom parts 16 formed of the n-type zinc oxide may be formed using a CVD method at a V/II ratio of about 200, a temperature of about 550° C., and a pressure of about 70 mbar, with diethyl zinc and oxygen gas as raw materials. In addition, the top parts 22 formed of the p-type zinc oxide may be formed by performing rapid annealing at a temperature of about 800° C. or more, after the zinc oxide is formed.

Next, referring to FIG. 2C, an insulating region 24 is formed between the nanorods 23. The insulating region 24 may be formed, for example, by mixing silicon oxide and magnesium fluoride using a Sol-Gel process.

The thus-formed insulating region 24 is formed higher than the nanorods 23 and thus may cover the nanorods 23. In this case, the top part of the insulating region 24 in FIG. 2C may be removed through wet etching, so that at least a portion of each of the top parts 22 of the nanorods 23 is exposed, as illustrated in FIG. 2D.

Finally, referring to FIG. 2E, a second electrode layer 26 is formed on top of the insulating region 24 so that the second electrode layer 26 electrically contacts the nanorods 23. Here, the second electrode layer 26 may be formed of platinum (Pt).

FIG. 3 is a scanning electron microscopic (SEM) image of nanorods formed using the process described with reference to FIG. 2B, according to an embodiment of the present invention. Referring to FIG. 3, it can be seen that the nanorods, which are formed of zinc oxide, and formed using the same conditions described above are well oriented in the C-axis direction from the basal layer. The mean height of the nanorods shown in FIG. 3 is about 2.6 μm, and the mean diameter of the nanorods is about 50 nm.

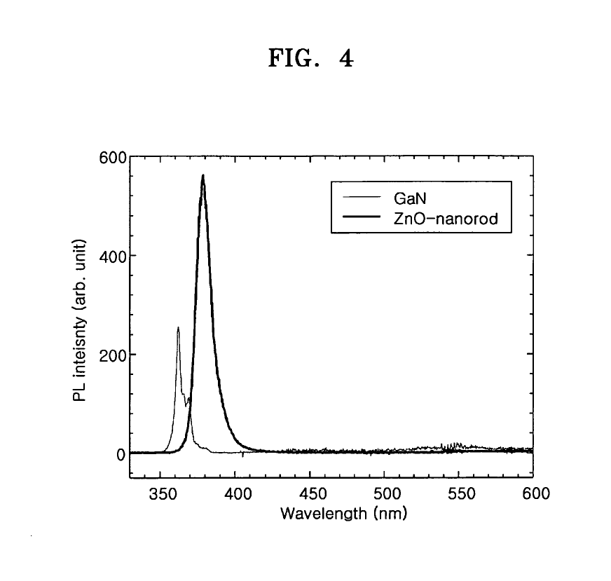

FIG. 4 is a graph illustrating a light-emitting characteristic of the light-emitting device 100 illustrated in FIG. 1, according to an embodiment of the present invention. Referring to FIG. 4, it can be seen that the light-emitting device 100 including the nanorods 23 formed of zinc oxide has good photoluminescence (PL) intensity and few defects compared to a light-emitting device including a GaN thin film.

While the light-emitting device using nanorods and the method of manufacturing the same according to the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A light-emitting device comprising:
a substrate;
a first electrode layer formed on top of the substrate;
a basal layer formed on the first electrode layer;
a plurality of nanorods formed vertically on the basal layer, each of the nanorods comprising:
a bottom part doped with first type;
a top part doped with second type opposite to the first type; and
an active layer between the bottom part and the top part;
an insulating region formed between the nanorods; and
a second electrode layer formed on the nanorods and the insulating region.

2. The light-emitting device of claim 1, wherein the basal layer and the bottom parts of the nanorods are formed of n-type zinc oxide, and the top parts of the nanorods are formed of p-type zinc oxide.

3. The light-emitting device of claim 1, wherein the basal layer and the bottom parts of the nanorods are formed of p-type zinc oxide, and the top parts of the nanorods are formed of n-type zinc oxide.

4. The light-emitting device of claim 1, wherein the insulating region is formed of one of silicon oxide, silicon nitride, and magnesium fluoride.

5. The light-emitting device of claim 1, wherein each of the first and the second electrode layers are formed of one of a transition metal and an alloy comprising the transition metal.

6. A light-emitting device comprising:
a conductive substrate;
a first electrode layer formed below the substrate;
a basal layer formed on top of the substrate;
a plurality of nanorods formed vertically on the basal layer, each of the nanorods comprising:
a bottom parts doped with first type;
a top part doped with second type opposite to the first type, and
an active layer between the bottom part and the top part;
an insulating region formed between the nanorods; and
a second electrode layer formed on the nanorods and the insulating region.

7. A method of manufacturing a light-emitting device comprising:
forming a first electrode layer on a substrate;
forming a basal layer on top of the first electrode layer;
forming a plurality of nanorods vertically on the basal layer, wherein each of the nanorods comprises a bottom part doped with first type, a top part doped with second type opposite to the first type, and an active layer between the bottom part and the top part;
forming an insulating region between the nanorods; and
forming a second electrode layer on the nanorods and the insulating region.

8. The method of claim 7, wherein the basal layer and the bottom parts of the nanorods are formed of n-type zinc oxide, and the top parts of the nanorods are formed of p-type zinc oxide.

9. The method of claim 7, wherein the basal layer and the bottom parts of the nanorods are formed of p-type zinc oxide, and the top parts of the nanorods are formed of n-type zinc oxide.

10. The method of claim 7, wherein the basal layer is formed using a chemical vapor-phase deposition (CVD) method at a V/II ratio of 10 to 1000, a temperature of 200 to 800° C., a pressure of 100 to 1000 mbar, with diethyl zinc and oxygen gas as raw materials.

11. The method of claim 7, wherein the thickness of the basal layer is less than 1 μm.

12. The method of claim 7, wherein the nanorods are formed using a CVD method at a V/II ratio of 10 to 1000, a temperature of 500 to 800° C., a pressure of 10 to 500 mbar, with diethyl zinc and oxygen gas as raw materials.

13. The method of claim 7, wherein the insulating region are formed of one of a group of materials consisting of silicon oxide, silicon nitride, and magnesium fluoride.

14. The method of claim 7, wherein the insulating region are formed of a mixture of silicon oxide and magnesium fluoride.

15. The method of claim 7, wherein the insulating region and the second electrode layer are disposed between the nanorods, such that the second electrode layer is above the insulating region.

16. The method of claim 7, wherein each of the first and the second electrode layer is formed of one of a transition metal and an alloy comprising the transition metal.
